(19) United States
(12) Patent Application Publication
(10) Pub. No.: US 2026/0074670 A1
(43) Pub. Date: Mar. 12, 2026

(54) PIEZOELECTRIC DEVICE

(71) Applicant: Murata Manufacturing Co., Ltd., Nagaokakyo-shi (JP)

(72) Inventor: Yutaka KISHIMOTO, Nagaokakyo-shi (JP)

(21) Appl. No.: 19/391,081

(22) Filed: Nov. 17, 2025

Related U.S. Application Data
(63) Continuation of application No. PCT/JP2024/022403, filed on Jun. 20, 2024.

(30) Foreign Application Priority Data
Jul. 3, 2023 (JP) 2023-109120

(51) Int. Cl. H03H 9/13; H03H 9/205

(52) U.S. Cl. CPC H03H 9/132; H03H 9/205

(57) ABSTRACT

A piezoelectric device includes a first piezoelectric layer including upper and lower surfaces, a first support on a lower surface side of the first piezoelectric layer, first upper and lower electrodes respectively on the upper and lower surfaces of the first piezoelectric layer at least partially facing each other, a second piezoelectric layer including upper and lower surfaces, a second support on a lower surface side of the second piezoelectric layer, and second upper and lower electrodes respectively on the upper and lower surfaces of the second piezoelectric layer at least partially facing the second upper electrode, and an intermediate layer. The upper surfaces of the first and second piezoelectric layers face each other in a first direction, and the intermediate layer is located between the upper surfaces of the first and second piezoelectric layers.

### CROSS REFERENCE TO RELATED APPLICATIONS

This application claims the benefit of priority to Japanese Patent Application No. 2023-109120 filed on Jul. 3, 2023 and is a Continuation Application of PCT Application No. PCT/JP2024/022403 filed on Jun. 20, 2024. The entire contents of each application are hereby incorporated herein by reference.

### BACKGROUND OF THE INVENTION

### 1. Field of the Invention

The present invention relates to piezoelectric devices.

### 2. Description of the Related Art

International Publication No. 2006/008940 describes a piezoelectric filter including a first substrate having a main surface on which a first resonator is formed, and a second substrate having a main surface on which a second resonator is formed. The first substrate and the second substrate are connected by columnar intermediate layers such that the main surface of the first substrate on which the first resonator is formed and the main surface of the second substrate on which the second resonator is formed face each other.

According to International Publication No. 2006/008940, the first substrate and the second substrate are connected by a frame-shaped connecting layer made of metal. In this case, the distance between a first piezoelectric layer where the first resonator is located and a second piezoelectric layer where the second resonator is located in the direction in which the first piezoelectric layer and the second piezoelectric layer face each other is not fixed during the manufacture of the piezoelectric filter. Thus, the distance between the first substrate and the second substrate has to be increased. This may increase the thickness of the piezoelectric device.

### SUMMARY OF THE INVENTION

Example embodiments of the present invention provide piezoelectric devices each with a small thickness.

A piezoelectric device according to an example embodiment of the present invention includes a first piezoelectric layer with a thickness in a first direction, the first piezoelectric layer including an upper surface being one surface of the first piezoelectric layer in the first direction, and a lower surface being another surface of the first piezoelectric layer in the first direction, a first support on a lower surface side of the first piezoelectric layer, a first upper electrode on the upper surface of the first piezoelectric layer, a first lower electrode on the lower surface of the first piezoelectric layer, the first lower electrode at least partially facing the first upper electrode, a second piezoelectric layer including an upper surface being one surface of the second piezoelectric layer in the first direction, and a lower surface being another surface of the second piezoelectric layer in the first direction, a second support on a lower surface side of the second piezoelectric layer, a second upper electrode on the upper surface of the second piezoelectric layer, a second lower electrode on the lower surface of the second piezoelectric layer, the second lower electrode at least partially facing the second upper electrode, and an intermediate layer. The upper surface of the first piezoelectric layer and the upper surface of the second piezoelectric layer face each other in the first direction, and the intermediate layer is located between the upper surface of the first piezoelectric layer and the upper surface of the second piezoelectric layer.

According to example embodiments of the present invention, piezoelectric devices each with a small thickness are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic sectional view illustrating an example of a piezoelectric device according to Example Embodiment 1 of the present invention.

FIG. 2 is a schematic plan view illustrating an example of an electrode provided on an upper surface of a first piezoelectric layer according to Example Embodiment 1 of the present invention.

FIG. 3 is a schematic plan view illustrating an example of an electrode provided on a lower surface of the first piezoelectric layer according to Example Embodiment 1 of the present invention.

FIG. 4 is a schematic sectional view for describing a lower electrode forming step according to Example Embodiment 1 of the present invention.

FIG. 5 is a schematic sectional view for describing a sacrificial layer forming step according to Example Embodiment 1 of the present invention.

FIG. 6 is a schematic sectional view for describing a first intermediate layer forming step according to Example Embodiment 1 of the present invention.

FIG. 7 is a schematic sectional view for describing a support substrate attaching step according to Example Embodiment 1 of the present invention.

FIG. 8 is a schematic sectional view for describing a piezoelectric layer thinning step according to Example Embodiment 1 of the present invention.

FIG. 9 is a schematic sectional view for describing an upper electrode forming step according to Example Embodiment 1 of the present invention.

FIG. 10 is a schematic sectional view for describing a second intermediate layer forming step according to Example Embodiment 1 of the present invention.

FIG. 11 is a schematic sectional view for describing a through hole forming step according to Example Embodiment 1 of the present invention.

FIG. 12 is a schematic sectional view for describing a space portion forming step according to Example Embodiment 1 of the present invention.

FIG. 13 is a schematic sectional view for describing a piezoelectric layer connecting step according to Example Embodiment 1 of the present invention.

FIG. 14 is a schematic sectional view illustrating an example of a piezoelectric device according to Example Embodiment 2 of the present invention.

FIG. 15 is a diagram for describing a piezoelectric layer connecting step of the piezoelectric device according to Example Embodiment 2 of the present invention.

FIG. 16 is a diagram for describing the piezoelectric layer connecting step of the piezoelectric device according to Example Embodiment 2 of the present invention.

FIG. 17 is a diagram for describing a support through hole forming step according to Example Embodiment 2 of the present invention.

FIG. 18 is a diagram for describing a space portion forming step according to Example Embodiment 2 of the present invention.

FIG. 19 is a schematic sectional view illustrating an example of a piezoelectric device according to Example Embodiment 3 of the present invention.

FIG. 20 is a diagram for describing a second sacrificial layer forming step according to Example Embodiment 3 of the present invention.

FIG. 21 is a diagram for describing a second intermediate layer forming step according to Example Embodiment 3 of the present invention.

FIG. 22 is a schematic sectional view for describing a piezoelectric layer connecting step according to Example Embodiment 3 of the present invention.

FIG. 23 is a diagram for describing a support through hole forming step according to Example Embodiment 3 of the present invention.

FIG. 24 is a diagram for describing a space portion forming step according to Example Embodiment 3 of the present invention.

FIG. 25 is a schematic sectional view illustrating an example of a piezoelectric device according to Example Embodiment 4 of the present invention.

### DETAILED DESCRIPTION OF THE EXAMPLE EMBODIMENTS

Example Embodiments of the present invention will be described in detail below with reference to the drawings. The present invention is not limited by the example embodiments. The example embodiments described in the present disclosure are merely examples. From Example Embodiment 2 and in modified examples in which the configurations of different example embodiments can be partially replaced or combined, points in common with Example Embodiment 1 are not described, and only different points are described. In particular, the same or similar operational and advantageous effects resulting from the same or similar configurations are not described in each example embodiment.

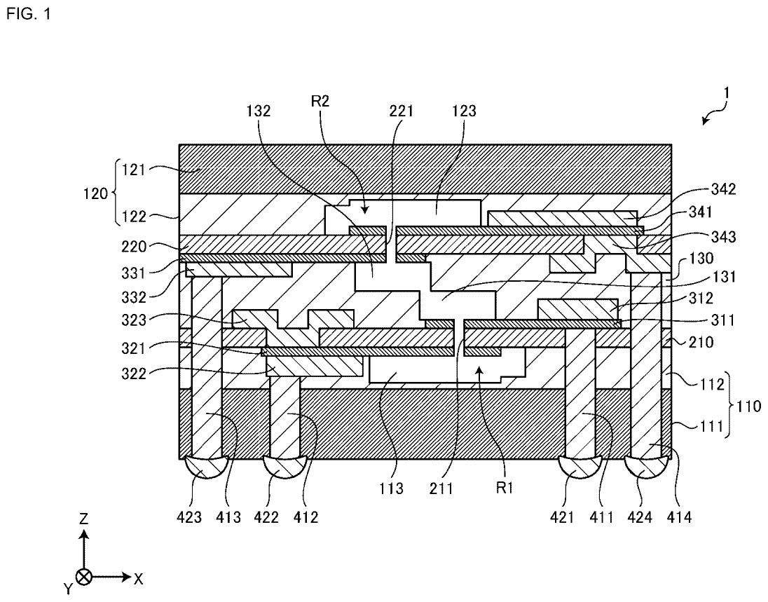

FIG. 1 is a schematic sectional view illustrating an example of a piezoelectric device according to Example Embodiment 1. A piezoelectric device 1 according to Example Embodiment 1 includes a first resonator R1, a second resonator R2, and an intermediate layer 130. The first resonator R1 and the second resonator R2 are resonators using bulk waves, that is, bulk acoustic wave (BAW) elements.

The first resonator R1 is a resonator including a support 110, a piezoelectric layer 210, an upper electrode 311, a wiring electrode 312 of the upper electrode, a lower electrode 321, and wiring electrodes 322 and 323 of the lower electrode 321. The first resonator R1 extends to the opposite side of the support 110 from a piezoelectric layer 220 via through electrodes 411 and 412 and bumps 421 and 422. Here, the support 110 is an example of a “first support”, the piezoelectric layer 210 is an example of a “first piezoelectric layer”, the upper electrode 311 is an example of a “first upper electrode”, and the lower electrode 321 is an example of a “first lower electrode”. However, a plurality of the resonators R1 may be configured to be connected in series or parallel. Thus, in this case, one of the resonators R1 may include one through electrode and one bump or may include no through electrode and no bump. In addition, in the following description, the thickness direction of the support 110 is the Z direction, a direction orthogonal or substantially orthogonal to the Z direction is the X direction, and a direction orthogonal or substantially orthogonal to the Z direction and the X direction is the Y direction.

The piezoelectric layer 210 is a flat layer including an upper surface 210a and a lower surface 210b opposite to the upper surface 210a. In Example Embodiment 1, the piezoelectric layer 210 is a substrate made of a single crystal of lithium niobate (LiNbO₃) or lithium tantalate (LiTaO₃), for example. The piezoelectric layer 210 may be a quartz crystal substrate, for example. The thickness of the piezoelectric layer 210 is not particularly limited and is, for example, preferably about 1 μm or less.

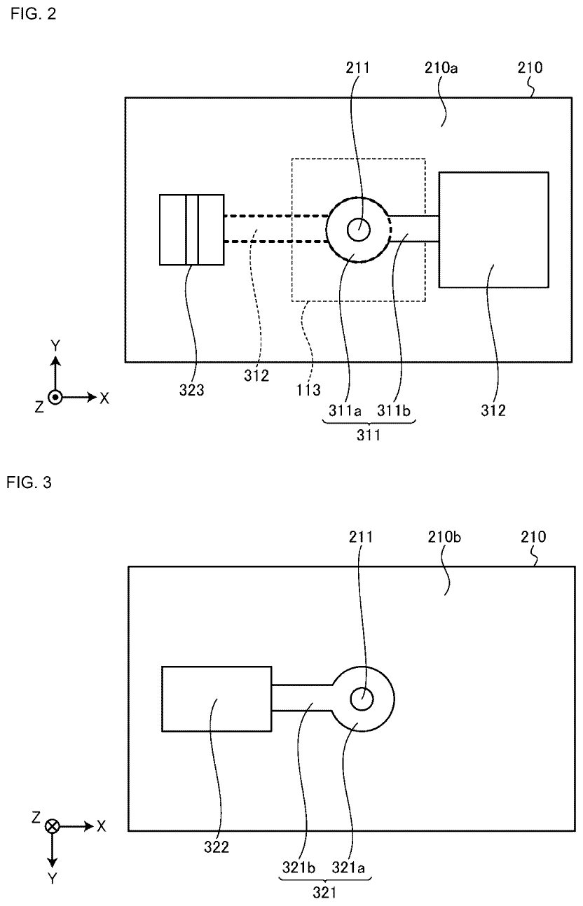

FIG. 2 is a schematic plan view illustrating an example of an electrode provided on an upper surface of a first piezoelectric layer according to Example Embodiment 1. As illustrated in FIG. 2, the upper electrode 311 is provided on the upper surface 210a of the piezoelectric layer 210. The upper electrode 311 includes a circular electrode 311a and an electrode 311b extending in the X direction from the electrode 311a. The wiring electrode 312 of the upper electrode is provided on the Z direction side of the electrode 311b. The wiring electrode 312 of the upper electrode is provided on the upper surface 210a side of the piezoelectric layer 210. The upper electrode 311 and the wiring electrode 312 of the upper electrode are made of a metal such as, for example, aluminum (Al), platinum (Pt), copper (Cu), tungsten (W), or molybdenum (Mo) or an alloy thereof. The upper electrode 311 and the wiring electrode 312 of the upper electrode may include an adhesion layer made of, for example, titanium (Ti) or nickel-chromium alloy (NiCr).

FIG. 3 is a schematic plan view illustrating an example of an electrode provided on a lower surface of the first piezoelectric layer according to Example Embodiment 1. As illustrated in FIG. 3, the lower electrode 321 is provided on the lower surface 210b of the piezoelectric layer 210. The lower electrode 321 includes a circular electrode 321a and an electrode 321b extending in the X direction from the electrode 321a. The wiring electrode 322 of the lower electrode is provided on the Z direction side of the electrode 321b. The wiring electrode 322 of the lower electrode is provided on the lower surface 210b side of the piezoelectric layer 210. The wiring electrode 323 of the lower electrode is provided on the upper surface 210a side of the piezoelectric layer 210 and passes through the piezoelectric layer 210. The lower electrode 321 and the wiring electrodes 322 and 323 of the lower electrode are made of a metal such as, for example, Al, Pt, Cu, W, or Mo or an alloy thereof. The lower electrode 321 and the wiring electrodes 322 and 323 of the lower electrode may include an adhesion layer made of, for example, Ti or NiCr.

In Example Embodiment 1, in plan view in the Z direction, the circular electrode 311a of the upper electrode 311 and the circular electrode 321a of the lower electrode 321 overlap each other. In other words, the piezoelectric layer 210 is between the circular electrode 311a of the upper electrode 311 and the circular electrode 321a of the lower electrode 321. Thus, a bulk wave is propagated between the circular electrode 311a of the upper electrode 311 and the circular electrode 321a of the lower electrode 321. The shape of each of the upper electrode 311 and the lower electrode 321 described above is merely an example, and the shape of each of the upper electrode 311 and the lower electrode 321 is not limited thereto. In the following description, in plan view in the Z direction, the region where the upper electrode 311 and the lower electrode 321 overlap each other is a first excitation region.

The support 110 faces the lower surface 210b of the piezoelectric layer 210. In Example Embodiment 1, the support 110 includes a support substrate 111 and an intermediate layer 112. The support substrate 111 is a substrate made of, for example, silicon (Si) or quartz crystal. The intermediate layer 112 is a layer provided on the piezoelectric layer 210 side of the support substrate 111 and is made of a dielectric such as, for example, silicon oxide. The support 110 may include only the support substrate 111 without the intermediate layer 112. In addition, an adhesion layer made of, for example, Ti or NiCr may be provided between the support substrate 111 and the intermediate layer 112.

The support 110 includes a space portion 113 in the surface of the support 110 facing the lower surface 210b of the piezoelectric layer 210. In Example Embodiment 1, the intermediate layer 112 includes the space portion 113 in the surface of the intermediate layer 112 facing the lower surface 210b of the piezoelectric layer 210. As illustrated in FIG. 2, the space portion 113 overlaps the first excitation region in plan view in the Z direction. Thus, a bulk wave is reflected by the space portion 113. In the example in FIG. 1, the shape of the space portion 113 is a rectangular shape, but is not limited thereto, and may be a different shape such as a circular shape, for example. In the example in FIG. 1, the space portion 113 is provided in the recess of the intermediate layer 112 and is surrounded by the intermediate layer 112 and the lower surface 210b of the piezoelectric layer 210. However, the configuration of the space portion 113 is not limited thereto, and the space portion 113 may pass through the intermediate layer 112, for example. In addition, when the support 110 includes the support substrate 111, the space portion 113 may be a space that is provided in the recess of the support substrate 111 and that is surrounded by the support substrate 111 and the lower surface 210b of the piezoelectric layer 210.

The piezoelectric layer 210 includes a through hole 211 communicating with a space portion 113. The through hole 211 is located at a position overlapping the space portion 113 in plan view in the Z direction. In the example in FIGS. 1 to 3, the through hole 211 is provided so as to pass through the circular electrode 311a of the upper electrode 311 and the circular electrode 321a of the lower electrode 321. However, the configuration of the through hole 211 is not limited thereto, and the through hole 211 does not have to pass through the upper electrode 311 and the lower electrode 321. It is sufficient that the through hole 211 is provided at a position overlapping the space portion 113.

The through electrodes 411 and 412 are extended electrodes of the first resonator R1 and are made of a conductor. The through electrode 411 is electrically connected to the upper electrode 311 via the wiring electrode 312. Similarly, the through electrode 412 is electrically connected to the lower electrode 321 via the wiring electrode 322. The through electrodes 411 and 412 are made of a conductor such as, for example, copper (Cu). The through electrode 411 passes through the support 110 and the piezoelectric layer 210 in the Z direction. The through electrode 412 passes through the support 110 in the Z direction.

The bumps 421 and 422 are terminals connectable to elements outside the piezoelectric device 1 and are, for example, ball grid array (BGA) bumps. The bumps 421 and 422 are provided on the opposite surface of the support 110 from the piezoelectric layer 210 in the Z direction. The bumps 421 and 422 are electrically connected to the through electrodes 411 and 412, respectively. Thus, the first resonator R1 is connectable to elements outside the piezoelectric device 1 via the through electrodes 411 and 412 and the bumps 421 and 422.

The second resonator R2 is similar to the first resonator R1 and includes a support 120, the piezoelectric layer 220, an upper electrode 331, wiring electrode 332 of the upper electrode, a lower electrode 341, and wiring electrodes 342 and 343 of the lower electrode 341. The second resonator R2 extends to the opposite side of the support 110 from the piezoelectric layer 220 via through electrodes 413 and 414 and bumps 423 and 424. Here, the support 120 is an example of a “second support”, the piezoelectric layer 220 is an example of a “second piezoelectric layer”, the upper electrode 331 is an example of a “second upper electrode”, and the lower electrode 341 is an example of a “second lower electrode”.

The piezoelectric layer 220 is a flat layer including an upper surface and the lower surface opposite to the upper surface. In Example Embodiment 1, the piezoelectric layer 220 is a substrate made of a single crystal of LiNbO₃, LiTaO₃, or quartz crystal, for example. The piezoelectric layer 220 may be another single-crystal piezoelectric substrate. The thickness of the piezoelectric layer 220 is not particularly limited and is, for example, preferably about 1 μm or less. The upper surface of the piezoelectric layer 220 faces the upper surface 210a of the piezoelectric layer 210. Here, the shortest distance between the upper surface of the piezoelectric layer 220 and the upper surface 210a of the piezoelectric layer 210 in the Z direction is, for example, preferably about 10 μm or less.

The upper electrode 331 is provided on the upper surface of the piezoelectric layer 220. The wiring electrode 332 of the upper electrode 331 is provided on the Z direction side of the upper electrode 331. In plan view in the Z direction, the upper electrode 331 is shaped so as to include a circular electrode and an electrode extending in the X direction similarly to the upper electrode 311 of the first resonator R1. The wiring electrode 332 of the upper electrode 331 is provided on the upper surface side of the piezoelectric layer 220. The lower electrode 341 is provided on the lower surface of the piezoelectric layer 220. The wiring electrodes 342 and 343 of the lower electrode are provided on the Z direction side of the lower electrode 341. The wiring electrode 342 of the lower electrode is provided on the lower surface side of the piezoelectric layer 220. In plan view in the Z direction, the lower electrode 341 is shaped so as to include a circular electrode and an electrode extending in the X direction similarly to the lower electrode 321 of the first resonator R1. The wiring electrode 343 of the lower electrode is provided on the upper surface side of the piezoelectric layer 220 and passes through the piezoelectric layer 220. The upper electrode 331, the lower electrode 341, and the wiring electrodes 332, 342, and 343 are made of a metal such as, for example, Al, Pt, Cu, W, or Mo or an alloy thereof. The upper electrode 331, the lower electrode 341, and the wiring electrodes 332, 342, and 343 may include an adhesion layer made of, for example, Ti or NiCr.

In Example Embodiment 1, in plan view in the Z direction, the circular electrode of the upper electrode 331 and the circular electrode of the lower electrode 341 overlap each other. In other words, the piezoelectric layer 220 is between the circular electrode of the upper electrode 331 and the circular electrode of the lower electrode 341. Thus, a bulk wave is propagated between the circular electrode of the upper electrode 331 and the circular electrode of the lower electrode 341. The shape of each of the upper electrode 331 and the lower electrode 341 described above is merely an example, and the shape of each of the upper electrode 311 and the lower electrode 321 is not limited thereto. In the following description, in plan view in the Z direction, the region where the upper electrode 331 and the lower electrode 341 overlap each other is a second excitation region.

The support 120 faces the lower surface of the piezoelectric layer 220. In Example Embodiment 1, the support 120 includes a support substrate 121 and an intermediate layer 122. The support substrate 121 is made of, for example, silicon (Si) or quartz crystal. The intermediate layer 122 is provided on the piezoelectric layer 220 side of the support substrate 121 and is made of a dielectric such as, for example, silicon oxide. The support 120 may include only the support substrate 121 without the intermediate layer 122. In addition, an adhesion layer made of, for example, Ti or NiCr may be provided between the support substrate 121 and the intermediate layer 122.

The support 120 includes the space portion 123 in the surface of the support 120 facing the lower surface of the piezoelectric layer 220. In Example Embodiment 1, the intermediate layer 122 includes the space portion 123 in the surface of the intermediate layer 122 facing the lower surface of the piezoelectric layer 220. As illustrated in FIG. 1, the space portion 123 overlaps the second excitation region in plan view in the Z direction. Thus, a bulk wave is reflected by the space portion 123. In the example in FIG. 1, the shape of the space portion 123 is a rectangular shape, but is not limited thereto, and may be a different shape such as a circular shape, for example. In the example in FIG. 1, the space portion 123 is provided in the recess of the intermediate layer 122 and is surrounded by the intermediate layer 122 and the lower surface 220b of the piezoelectric layer 220. However, the configuration of the space portion 123 is not limited thereto, and the space portion 123 may pass through the intermediate layer 122, for example. In addition, when the support 120 includes the support substrate 121, the space portion 123 may be provided in the recess of the support substrate 121 and surrounded by the support substrate 121 and the lower surface 220b of the piezoelectric layer 220.

The piezoelectric layer 220 includes the through hole 221 communicating with a space portion 123. The through hole 221 is located at a position overlapping the space portion 123 in plan view in the Z direction. In the example in FIG. 1, the through hole 221 passes through the circular electrode of the upper electrode 331 and the circular electrode of the lower electrode 341. However, the configuration of the through hole 221 is not limited thereto, and the through hole 221 does not have to pass through the upper electrode 331 and the lower electrode 341. It is sufficient that the through hole 221 be provided at a position overlapping the space portion 123.

The through electrodes 413 and 414 are extended electrodes of the second resonator R2 and are made of a conductor. The through electrode 413 is electrically connected to the upper electrode 331 via the wiring electrode 332. Similarly, the through electrode 414 is electrically connected to the lower electrode 341 via the wiring electrode 342. The through electrodes 413 and 414 are made of a conductor such as, for example, Cu. The through electrodes 413 and 414 pass through the intermediate layer 130 described later, the piezoelectric layer 210, and the support 110 in the Z direction.

The bumps 423 and 424 are terminals connectable to elements outside the piezoelectric device 1 and are, for example, ball grid array (BGA) bumps. The bumps 423 and 424 are provided on the opposite surface of the support 110 from the piezoelectric layer 220 in the Z direction. The bumps 423 and 424 are electrically connected to the through electrodes 413 and 414, respectively. Thus, the second resonator R2 is connectable to elements outside the piezoelectric device 1 via the through electrodes 413 and 414 and the bumps 423 and 424. However, as described above, a plurality of the resonators R2 may be configured to be connected in series or parallel. Thus, in this case, one of the resonators R2 may include one through electrode and one bump or may include no through electrode and no bump.

The intermediate layer 130 is located between the piezoelectric layer 210 and the piezoelectric layer 220. In Example Embodiment 1, the intermediate layer 130 is between the upper surface 210a of the piezoelectric layer 210 and the upper surface of the piezoelectric layer 220. In other words, the intermediate layer 130 is filled in the space excluding a space portion 131 and a space portion 132 between the upper surface of the piezoelectric layer 210 and the upper surface of the piezoelectric layer 220. In Example Embodiment 1, the intermediate layer 130 is made of an insulator such as, for example, silicon oxide. Thus, the piezoelectric device 1 can be reduced in size and can be improved in piezoelectricity. The intermediate layer 130 is not limited to a layer made of a single material and may be a multilayer body including a plurality of insulator layers. In addition, the intermediate layer 130 may include an adhesion layer made of, for example, Ti or NiCr.

The intermediate layer 130 includes space portions. In Example Embodiment 1, the intermediate layer 130 includes the space portions 131 and 132. In Example Embodiment 1, the space portion 131 is located at a position overlapping the first excitation region in plan view in the Z direction of the intermediate layer 130. In addition, the space portion 131 is provided in the recess located on the piezoelectric layer 210 side of the intermediate layer 130 and is surrounded by the intermediate layer 130, the piezoelectric layer 210, and the upper electrode 311. Thus, a bulk wave of the first resonator R1 is reflected by the space portion 131. The space portion 132 is located at a position overlapping the second excitation region in plan view in the Z direction of the intermediate layer 130. In addition, the space portion 132 is provided in the recess located on the piezoelectric layer 220 side of the intermediate layer 130 and is surrounded by the intermediate layer 130, the piezoelectric layer 220, and the upper electrode 331. Thus, a bulk wave of the second resonator R2 is reflected by the space portion 132. In Example Embodiment 1, the space portions 131 and 132 are sealed off from the outside of the piezoelectric device 1. Thus, it is possible to reduce or prevent, for example, moisture and dust in air from entering the space portions 131 and 132 and to thus improve the reliability of the piezoelectric device 1.

In the example in FIG. 1, the space portions 131 and 132 communicate with each other in the Z direction. Thus, the first excitation region and the second excitation region can be close to each other and not overlap each other in the Z direction. Accordingly, it is possible to reduce the size of the piezoelectric device 1 in the direction orthogonal to the Z direction. The configuration is not limited thereto, and the space portions 131 and 132 may define one space. For example, the intermediate layer 130 may include a space portion that is provided at a position overlapping the first excitation region and the second excitation region in plan view in the Z direction and that passes through the intermediate layer 130 in the Z direction. In addition, in the example in FIG. 1, the space portions 131 and 132 communicate with the space portions 113 and 123 via the through holes 211 and 221, respectively, but the configuration is not limited thereto, and the space portions 131 and 132 do not have to communicate with the space portions 113 and 123.

The piezoelectric device 1 has been described above. However, the piezoelectric device according to Example Embodiment 1 is not limited to the piezoelectric device illustrated in FIG. 1.

For example, the piezoelectric device may be formed by laminating three or more piezoelectric layers in the Z direction. In this case, an upper electrode and a lower electrode are provided on the outermost piezoelectric layer in the Z direction (other than the first piezoelectric layer and the second piezoelectric layer). The outermost piezoelectric layer is between two intermediate layers. In this case, each intermediate layer preferably includes a space portion located at a position overlapping, in plan view in the Z direction, an excitation region of a resonator adjacent thereto in the Z direction.

In addition, for example, a resonator sharing a common piezoelectric layer may be further provided. That is, a plurality of pairs of upper electrodes and lower electrodes may be provided on one piezoelectric layer to define a plurality of resonators.

In addition, for example, a piezoelectric layer may further include other elements and wiring lines. A resonator and the other elements may be electrically connected to each other via the wiring lines.

As described above, the piezoelectric device 1 according to Example Embodiment 1 includes the first piezoelectric layer (piezoelectric layer 210) having a thickness in a first direction, the first piezoelectric layer including the upper surface being one surface of the first piezoelectric layer in the first direction, and the lower surface being the other surface of the first piezoelectric layer in the first direction, the first support (support 110) provided on the lower surface side of the first piezoelectric layer, the first upper electrode (upper electrode 311) provided on the upper surface of the first piezoelectric layer, the first lower electrode (lower electrode 321) provided on the lower surface of the first piezoelectric layer, the first lower electrode at least partially facing the first upper electrode, the second piezoelectric layer (piezoelectric layer 220) including the upper surface being one surface of the second piezoelectric layer in the first direction, and the lower surface being the other surface of the second piezoelectric layer in the first direction, the second support (support 120) provided on the lower surface side of the second piezoelectric layer, the second upper electrode (upper electrode 331) provided on the upper surface of the second piezoelectric layer, the second lower electrode (lower electrode 341) provided on the lower surface of the second piezoelectric layer, the second lower electrode at least partially facing the second upper electrode, and the intermediate layer 130. The upper surface of the first piezoelectric layer and the upper surface of the second piezoelectric layer face each other in the first direction. The intermediate layer is located between the upper surface of the first piezoelectric layer and the upper surface of the second piezoelectric layer. Thus, in a step of forming the intermediate layer 130, the thickness of the intermediate layer 130 is adjusted. Accordingly, it is possible to adjust the distance between the upper surface of the first piezoelectric layer and the upper surface of the second piezoelectric layer and to thus provide the piezoelectric device 1 having a small thickness.

According to an example embodiment of the present invention, the piezoelectric device 1 further includes the through electrodes 413 and 414 connected to at least one of the second upper electrode and the second lower electrode. The through electrodes 413 and 414 pass through the first support. Thus, the first resonator R1 and the second resonator R2 extend to the surface of the piezoelectric device 1 on the same side in the Z direction via the through electrodes 411 to 414. Thus, it is possible to simplify the wiring connected to the piezoelectric device 1.

According to an example embodiment of the present invention, when the region where the first upper electrode and the first lower electrode face each other in the first direction is the first excitation region and the region where the second upper electrode and the second lower electrode face each other in the first direction is the second excitation region, the first support includes a first space portion (space portion 113) located at a position overlapping at least a portion of the first excitation region, and the second support includes a second space portion (space portion 123) located at a position overlapping at least a portion of the second excitation region. Thus, bulk waves excited by the first resonator R1 and the second resonator R2 are reflected by the space portions 113 and 123. Accordingly, it is possible to improve the frequency characteristics.

According to an example embodiment of the present invention, when the region where the first upper electrode and the first lower electrode face each other in the first direction is the first excitation region and the region where the second upper electrode and the second lower electrode face each other in the first direction is the second excitation region, the intermediate layer 130 includes the space portions 131 and 132 located at respective positions overlapping at least a portion of the first excitation region and at least a portion of the second excitation region in plan view in the first direction. Thus, bulk waves excited by resonators (the first resonator R1 and the second resonator R2) adjacent to the intermediate layer 130 in the Z direction are reflected by the space portions 131 and 132. Accordingly, it is possible to improve the frequency characteristics.

According to an example embodiment of the present invention, the space portion 131 of the intermediate layer 130 is sealed off from the outside of the piezoelectric device 1. Thus, it is possible to reduce or prevent, for example, moisture and dust in air outside the piezoelectric device 1 from entering the space portion 131 of the intermediate layer 130. Thus, it is possible to improve the reliability of the piezoelectric device 1.

According to an example embodiment of the present invention, the first piezoelectric layer and the second piezoelectric layer include single-crystal lithium niobate, single-crystal lithium tantalate, or quartz crystal. Thus, it is possible to improve the resonance characteristics of the piezoelectric device 1.

A non-limiting example of a method for manufacturing the piezoelectric device 1 according to Example Embodiment 1 will be described below. The method for manufacturing the piezoelectric device according to Example Embodiment 1 includes a lower electrode forming step, a sacrificial layer forming step, a first intermediate layer forming step, a support substrate attaching step, a piezoelectric layer thinning step, an upper electrode forming step, a second intermediate layer forming step, a through hole forming step, a space portion forming step, a piezoelectric layer connecting step, and a through electrode forming step.

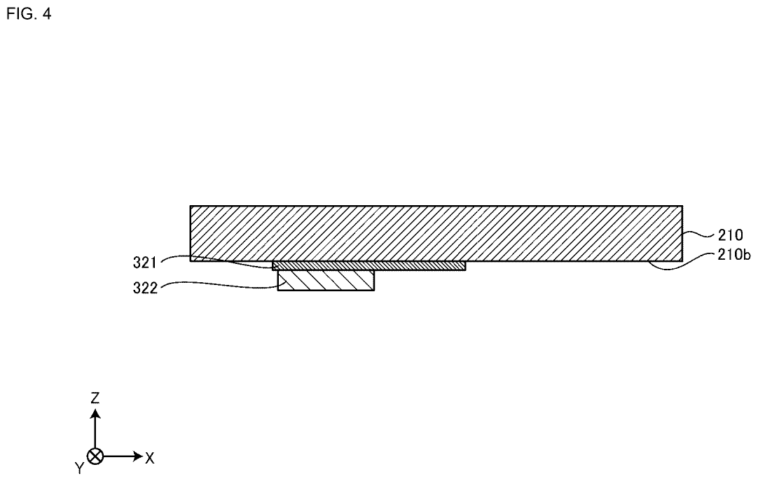

FIG. 4 is a schematic sectional view for describing a lower electrode forming step according to Example Embodiment 1. As illustrated in FIG. 4, the lower electrode forming step is a step of forming the lower electrode 321 on the lower surface 210b of the piezoelectric layer 210. In the lower electrode forming step, the wiring electrode 322 of the lower electrode 321 is formed after the formation of the lower electrode 321. The wiring electrode 322 is formed under the lower surface 210b of the piezoelectric layer 210 so as to cover a portion of the lower electrode 321. In Example Embodiment 1, the lower electrode 321 and the wiring electrode 322 of the lower electrode 321 are formed by, for example, a vapor deposition lift-off process in which a resist is patterned by photolithography, a metal film is deposited thereon, and the resist is removed. After the formation of the lower electrode 321 and the wiring electrode 322 of the lower electrode 321, the surface opposite to the piezoelectric layer 210 may be flattened by, for example, chemical-mechanical polishing (CMP).

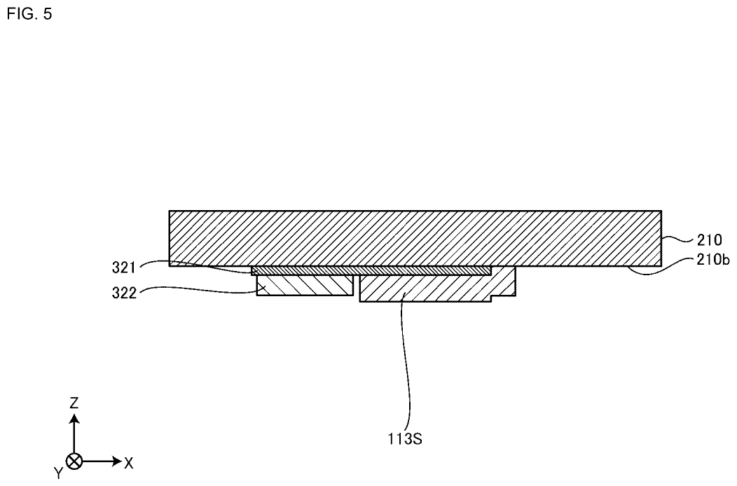

FIG. 5 is a schematic sectional view for describing a sacrificial layer forming step according to Example Embodiment 1. As illustrated in FIG. 5, the sacrificial layer forming step is a step of forming a sacrificial layer 113S on the lower surface 210b of the piezoelectric layer 210 so as to cover the portion of the lower electrode 321 located at a position overlapping the excitation region. In Example Embodiment 1, the sacrificial layer 113S is a layer made of zinc oxide and is formed by sputtering, for example.

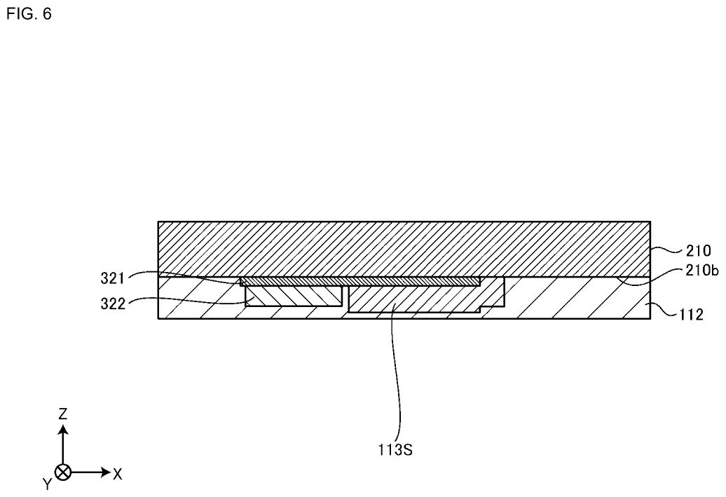

FIG. 6 is a schematic sectional view for describing a first intermediate layer forming step according to Example Embodiment 1. As illustrated in FIG. 6, the first intermediate layer forming step is a step of forming the intermediate layer 112 on the lower surface 210b of the piezoelectric layer 210 so as to cover the lower electrode 321, the wiring electrode 322 of the lower electrode 321, and the sacrificial layer 113S. In Example Embodiment 1, for example, the intermediate layer 112 is formed by sputtering, and the surface thereof opposite to the piezoelectric layer 210 is then flattened by CMP.

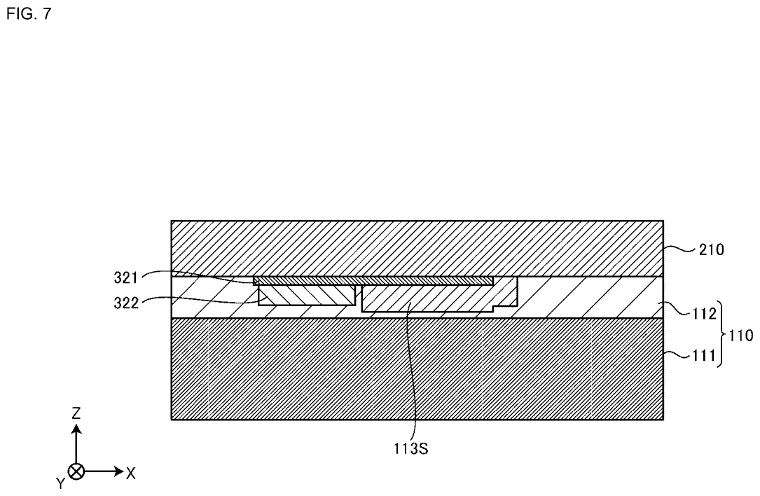

FIG. 7 is a schematic sectional view for describing a support substrate attaching step according to Example Embodiment 1. As illustrated in FIG. 7, the support substrate attaching step is a step of attaching the support substrate 111 to the opposite side of the intermediate layer 112 from the piezoelectric layer 210. In Example Embodiment 1, the support substrate 111 is connected to the intermediate layer 112 by, for example, fusion bonding, direct bonding (SDB: silicon wafer direct-bonding), plasma activated bonding, or atomic diffusion bonding.

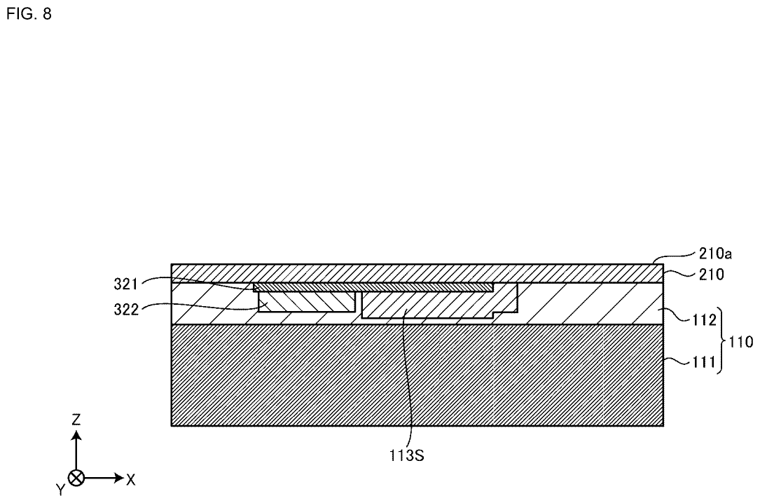

FIG. 8 is a schematic sectional view for describing a piezoelectric layer thinning step according to Example Embodiment 1. As illustrated in FIG. 8, the piezoelectric layer thinning step is a step of reducing the thickness of the piezoelectric layer 210 to form the upper surface 210a. In Example Embodiment 1, for example, the piezoelectric layer 210 is thinned by grinding or CMP, but the thinning method is not limited thereto. For example, the piezoelectric layer 210 may be thinned such that a damaged layer is formed in the piezoelectric layer 210 by ion implantation and an upper layer of the formed damaged layer is removed.

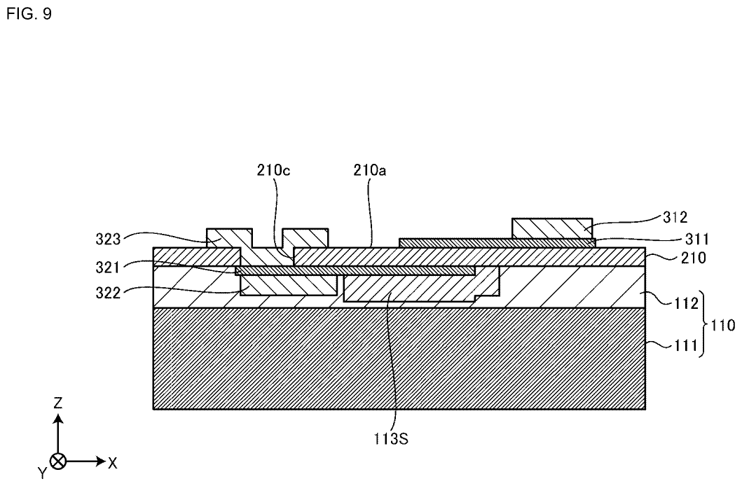

FIG. 9 is a schematic sectional view for describing an upper electrode forming step according to Example Embodiment 1. As illustrated in FIG. 9, the upper electrode forming step is a step of forming the upper electrode 311 on the upper surface 210a of the piezoelectric layer 210 at a position overlapping at least a portion of the lower electrode 321 in plan view in the Z direction. In the upper electrode forming step, after the formation of the upper electrode 311, a cavity 210c is provided in the piezoelectric layer 210, and the wiring electrode 323 of the lower electrode 321 and the wiring electrode 312 of the upper electrode 311 are then formed. The cavity 210c is formed at a position overlapping the lower electrode 321 in plan view in the Z direction so as to pass through the piezoelectric layer 210 in the Z direction. The wiring electrode 323 is formed on the upper surface 210a of the piezoelectric layer 210 so as to cover the portion of the lower electrode 321 exposed to the cavity 210c. Thus, the lower electrode 321 is extended to the upper surface 210a of the piezoelectric layer 210 via the wiring electrode 323. The wiring electrode 312 is formed above the upper surface 210a of the piezoelectric layer 210 so as to cover portion of the upper electrode 311. In Example Embodiment 1, the upper electrode 311 and the wiring electrodes 312 and 323 are formed by, for example, a vapor deposition lift-off process in which a resist is patterned by photolithography, a metal film is deposited thereon, and the resist is removed. After the formation of the upper electrode 311 and the wiring electrodes 312 and 323, the opposite surface of each of the upper electrode 311 and the wiring electrodes 312 and 323 from the piezoelectric layer 210 may be flattened by CMP, for example. In addition, in Example Embodiment 1, the cavity 210c is formed by removing portion of the piezoelectric layer 210 by reactive ion etching (RIE).

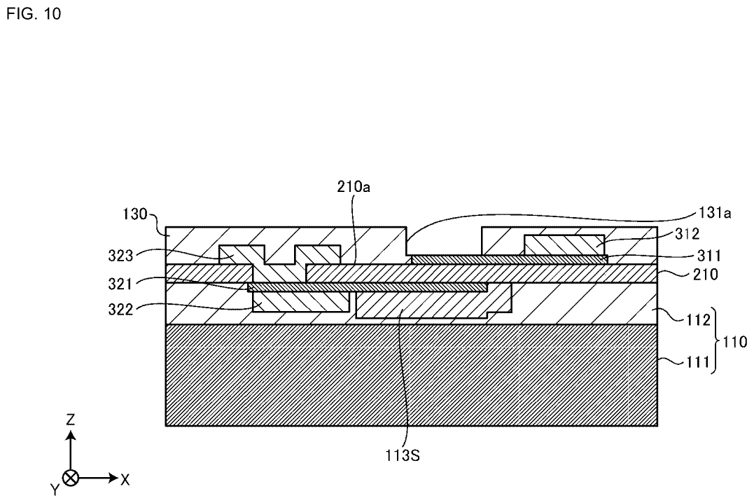

FIG. 10 is a schematic sectional view for describing a second intermediate layer forming step according to Example Embodiment 1. As illustrated in FIG. 10, the second intermediate layer forming step is a step of providing the intermediate layer 130 on the upper surface 210a of the piezoelectric layer 210 so as to cover the upper electrode 311, the wiring electrode 312 of the upper electrode 311, and the wiring electrode 323 of the lower electrode 321. Accordingly, the distance between the upper surface of the piezoelectric layer 210 and the upper surface of the piezoelectric layer 220 can be reduced by adjusting the thickness of the intermediate layer 130, thus enabling a reduction in the thickness of the piezoelectric device 1. In Example Embodiment 1, for example, the intermediate layer 130 is formed such that a multilayer is formed by sputtering and the opposite surface thereof from the piezoelectric layer 210 is then flattened by CMP.

In the second intermediate layer forming step, after the formation of the intermediate layer 130, a cavity 131a is formed at a position overlapping the excitation region in plan view in the Z direction. Thus, in a piezoelectric layer connecting step described later, the cavity 131a is closed to form the space portion 131. In Example Embodiment 1, the cavity 131a is formed by patterning, for example.

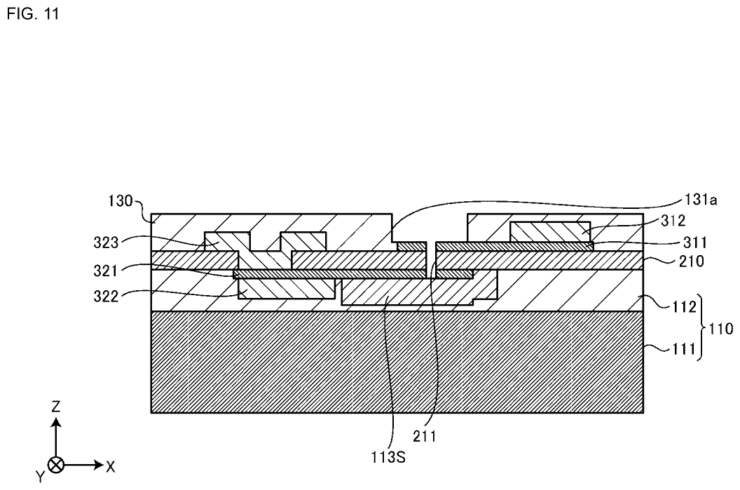

FIG. 11 is a schematic sectional view for describing a through hole forming step according to Example Embodiment 1. As illustrated in FIG. 11, the through hole forming step is a step of providing the through hole 211 in the piezoelectric layer 210. The through hole 211 is provided at a position, inside the cavity 131a, overlapping the sacrificial layer 113S in plan view in the Z direction. In Example Embodiment 1, the through hole 211 is formed by RIE, for example.

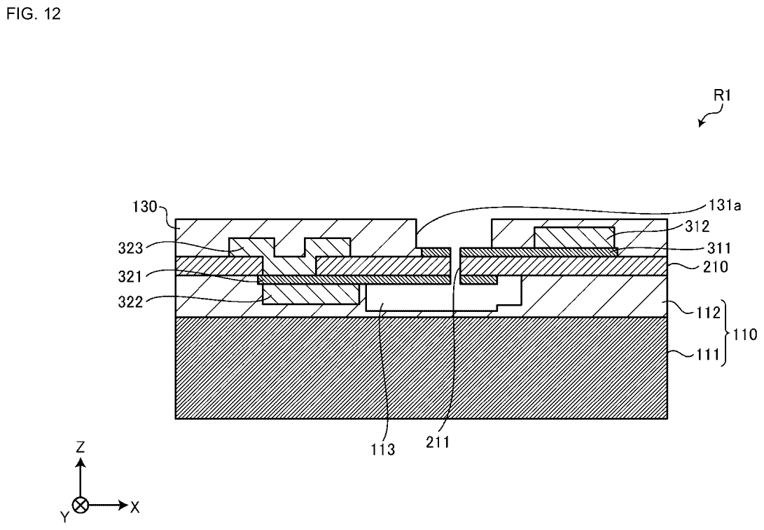

FIG. 12 is a schematic sectional view for describing a space portion forming step according to Example Embodiment 1. As illustrated in FIG. 12, the space portion forming step is a step of removing the sacrificial layer 113S to form the space portion 113. In Example Embodiment 1, the sacrificial layer 113S is removed by wet etching, for example. In this case, an etchant for dissolving the sacrificial layer 113S is injected through the through hole 211. Thus, a multilayer body including the first resonator R1 is produced.

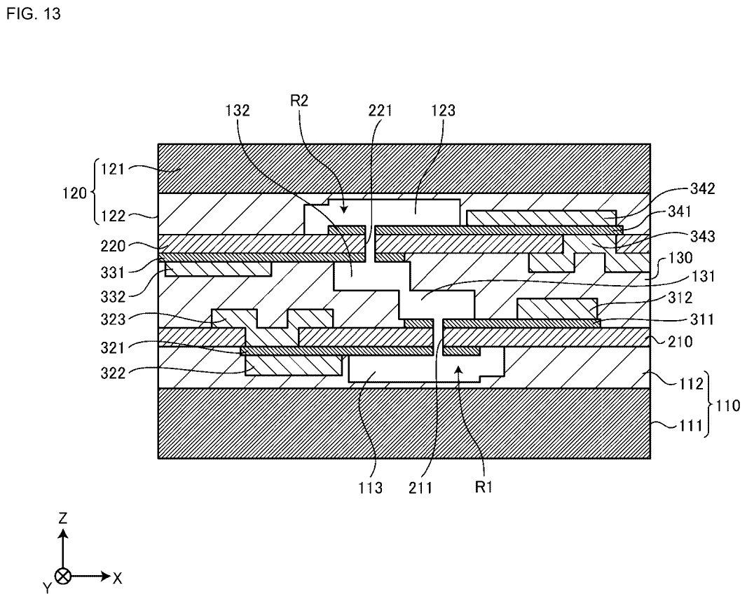

FIG. 13 is a schematic sectional view for describing a piezoelectric layer connecting step according to Example Embodiment 1. As illustrated in FIG. 13, the piezoelectric layer connecting step is a step of connecting, via each intermediate layer 130, the piezoelectric layer 210 of the multilayer body including the first resonator R1 and the piezoelectric layer 220 of a multilayer body including the second resonator R2 produced by a method the same as or similar to the method for producing the multilayer body including the first resonator R1 described above. In Example Embodiment 1, the piezoelectric layer 210 and the piezoelectric layer 220 are connected by, for example, fusion bonding, direct bonding (SDB), plasma activated bonding, or atomic diffusion bonding. In addition, in Example Embodiment 1, the attachment of the intermediate layers 130 to each other forms the space portions 131 and 132 in the combined intermediate layer 130. In the piezoelectric layer connecting step, after the connection, the support substrates 111 and 121 are thinned by grinding as appropriate. Thus, it is possible to reduce the thickness of the piezoelectric device.

The through electrode forming step is a step of forming the through electrodes 411 to 414 so as to pass through the support 110. In Example Embodiment 1, a plurality of holes are formed so as to pass through from the opposite main surface of the support 110 from the piezoelectric layer 210 to the upper electrode 311 and the wiring electrodes 322, 332, and 343 in the Z direction, and the formed holes are filled by filling plating to form the through electrodes 411 to 414. In Example Embodiment 1, the holes in which the through electrodes 411 to 414 are provided are formed by deep RIE (DRIE), for example. In the through electrode forming step, after the formation of the through electrodes 411 to 414, the bumps 421 to 424 are formed at the respective exposed end portions of the through electrodes 411 to 414.

The piezoelectric device 1 according to Example Embodiment 1 can be manufactured by using the above steps. The method for manufacturing the piezoelectric device 1 described above is merely an example. The method for manufacturing the piezoelectric device 1 is not limited thereto, and this method may be changed as appropriate.

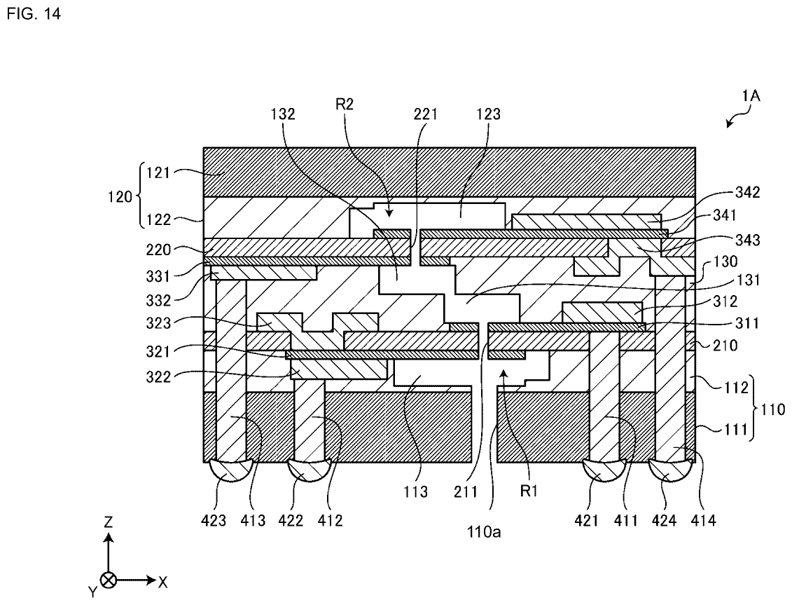

FIG. 14 is a schematic sectional view illustrating an example of a piezoelectric device according to Example Embodiment 2 of the present invention. As illustrated in FIG. 14, a piezoelectric device 1A according to Example Embodiment 2 differs from the piezoelectric device according to Example Embodiment 1 in that a through hole 110a communicating with the space portion 113 is provided in the support 110.

In Example Embodiment 2, the through hole 110a communicating with the space portion 113 is provided in the support 110. The through hole 110a is provided at a position overlapping the space portion 113 in plan view in the Z direction and communicates with the space portion 113. The through hole 110a passes through the support substrate 111 in the Z direction. Thus, in the process for manufacturing the piezoelectric device 1A, it is possible to reduce or prevent the piezoelectric device 1A from being damaged by forming the space portions 113 and 123.

As described above, in the piezoelectric device 1A according to Example Embodiment 2, the first support includes the through hole 110a. The first space portion and the second space portion communicate with the through hole 110a. In this case, in a process for manufacturing the piezoelectric device 1A according to Example Embodiment 2 described later, a piezoelectric layer connecting step is performed before a space portion forming step. Thus, it is possible to reduce or prevent the piezoelectric device 1A from being damaged by the step after the formation of the space portions 113 and 123.

In addition, in the piezoelectric device 1A according to Example Embodiment 2, the first support includes the through hole 110a communicating with the space portions 131 and 132 in the intermediate layer 130. Thus, even after the piezoelectric layer connecting step, it is possible to inject an etchant to dissolve the sacrificial layers into the space portions 131 and 132.

A non-limiting example of a method for manufacturing the piezoelectric device according to Example Embodiment 2 will be described below. The method for manufacturing the piezoelectric device according to Example Embodiment 2 is the same as or similar to the method according to Example Embodiment 1 in the steps to the through hole forming step, and these same or similar steps are thus not described.

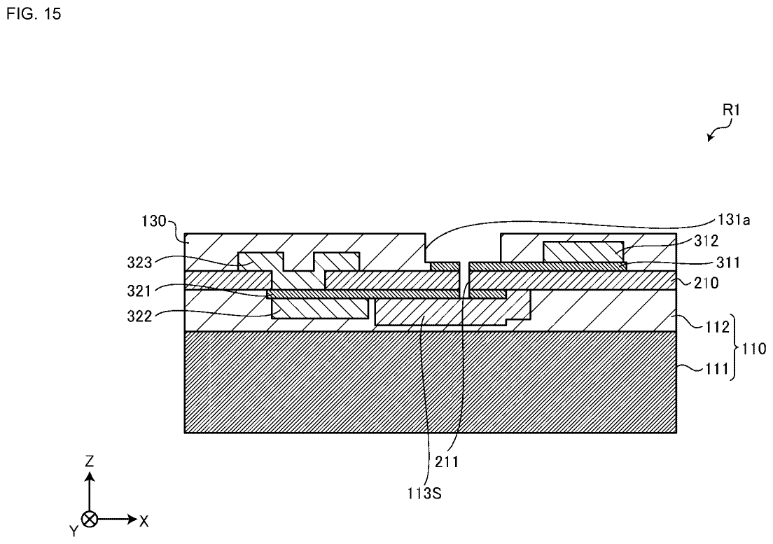

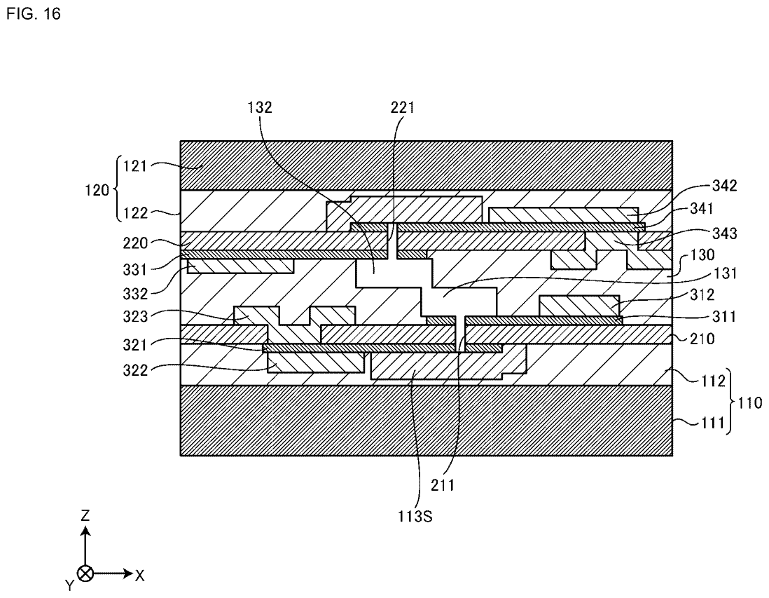

FIGS. 15 and 16 are diagrams for describing a piezoelectric layer connecting step of the piezoelectric device according to Example Embodiment 2. More specifically, FIG. 15 is a schematic sectional view illustrating a multilayer body including the first resonator R1 before the piezoelectric layer connecting step. FIG. 16 is a schematic sectional view illustrating a body formed by connecting the multilayer body including the first resonator R1 and a multilayer body including the second resonator R2 after the piezoelectric layer connecting step. As illustrated in FIGS. 15 and 16, in Example Embodiment 2, the space portion forming step is not performed subsequent to the through hole forming step, but the piezoelectric layer connecting step is performed subsequent to the through hole forming step. Thus, it is possible to reduce or prevent the piezoelectric device 1A from being damaged by the piezoelectric layer connecting step.

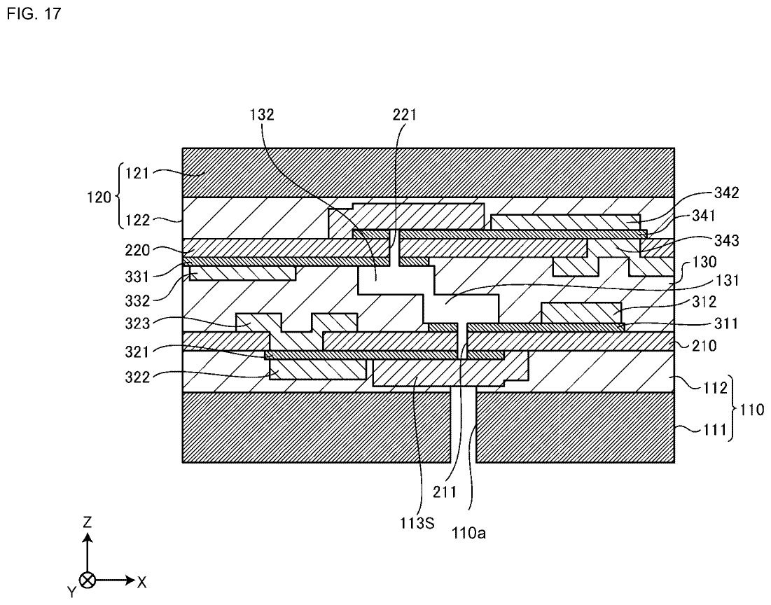

FIG. 17 is a diagram for describing a support through hole forming step according to Example Embodiment 2. As illustrated in FIG. 17, in the support through hole forming step, the through hole 110a is formed so as to pass through from the opposite surface of the support 110 from the piezoelectric layer 210 to the sacrificial layer 113S in the Z direction. In Example Embodiment 2, the through hole 110a is formed by DRIE, for example.

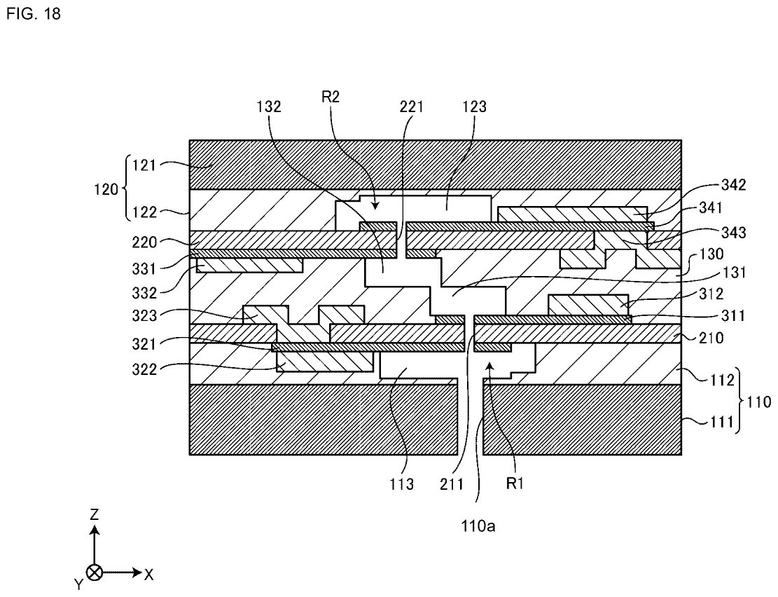

FIG. 18 is a diagram for describing a space portion forming step according to Example Embodiment 2. As illustrated in FIG. 18, the space portion forming step is a step of removing the sacrificial layers 113S and 123S to form the space portions 113 and 123. In Example Embodiment 2, the sacrificial layers 113S and 123S are removed by wet etching, for example. In this case, an etchant for dissolving the sacrificial layers 113S and 123S is injected through the through hole 110a. More specifically, after the etchant is injected through the through hole 110a and dissolves the sacrificial layer 113S, the etchant reaches the sacrificial layer 123S through the through hole 211, the space portions 131 and 132, and the through hole 221 to dissolve the sacrificial layer 123S.

Subsequently, a through electrode forming step the same as or similar to that in Example Embodiment 1 is performed. Thus, it is possible to manufacture the piezoelectric device 1A according to Example Embodiment 2. The method for manufacturing the piezoelectric device 1A described above is merely an example. The method for manufacturing the piezoelectric device 1A is not limited thereto, and this method may be changed as appropriate.

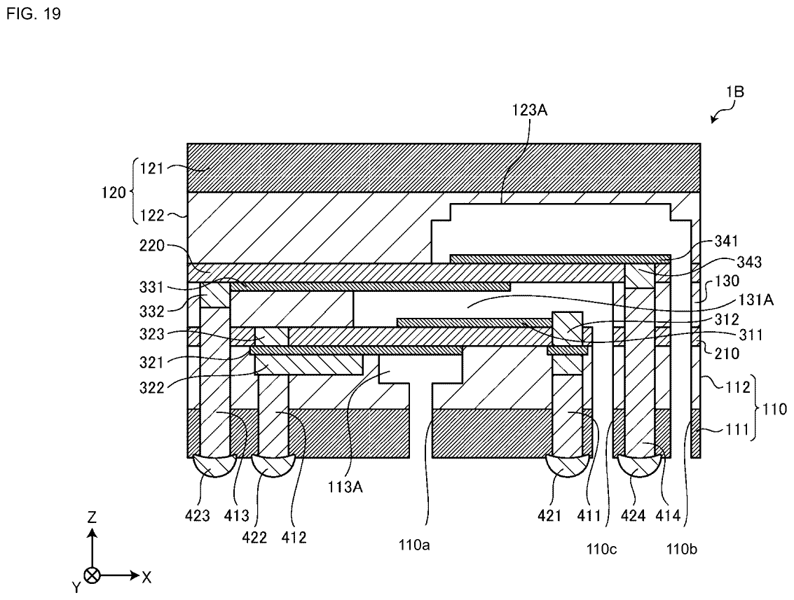

FIG. 19 is a schematic sectional view illustrating an example of a piezoelectric device according to Example Embodiment 3 of the present invention. As illustrated in FIG. 19, the piezoelectric device 1B according to Example Embodiment 3 differs from the piezoelectric device according to Example Embodiment 1 in that the support 110 includes through holes 110a, 110b, and 110c communicating with space portions 113A, 123A, and 131A, respectively.

In Example Embodiment 3, the support 110 includes the through holes 110a to 110c communicating with the space portion 113A, 123A, and 131A. The through holes 110a, 110b, and 110c are provided at respective positions overlapping the space portions 113A, 123A, and 131A in plan view in the Z direction and communicate with the space portions 113A, 123A, and 131A, respectively. The through hole 110a passes through the support substrate 111 in the Z direction. The through hole 110c passes through the support substrate 111 and the piezoelectric layer 210 in the Z direction. The through hole 110b passes through the support substrate 111, the piezoelectric layer 210, the intermediate layer 130, and the piezoelectric layer 220 in the Z direction.

As described above, in a piezoelectric device 1B according to Example Embodiment 3, the support 110 includes the through hole 110c communicating with the space portion 131A in the intermediate layer 130. In this case, in a process for manufacturing the piezoelectric device 1B according to Example Embodiment 3 described later, it is possible to perform a piezoelectric layer connecting step in a state in which the space portion 131 is not formed and to thus reduce or prevent the piezoelectric device 1B from being damaged by the piezoelectric layer connecting step.

A non-limiting example of a method for manufacturing the piezoelectric device according to Example Embodiment 3 will be described below. The method for manufacturing the piezoelectric device according to Example Embodiment 3 is the same as or similar to the method according to Example Embodiment 1 in the steps to the upper electrode forming step, and these similar steps are thus not described.

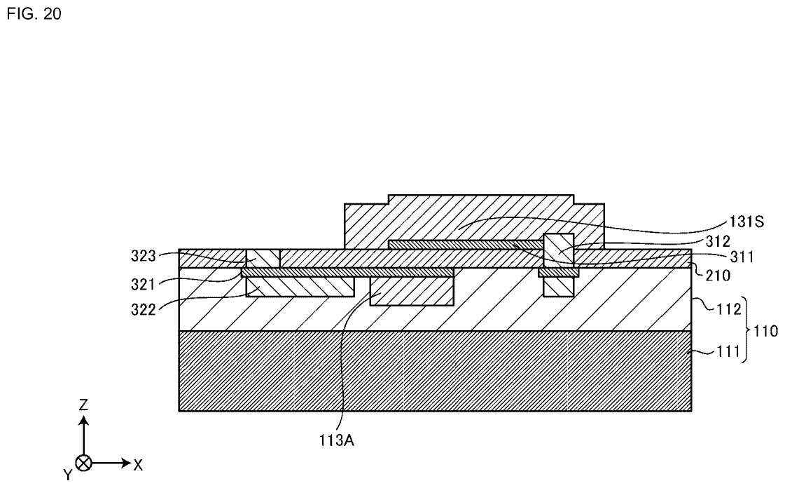

FIG. 20 is a diagram for describing a second sacrificial layer forming step according to Example Embodiment 3. As illustrated in FIG. 20, the second sacrificial layer forming step is a step of forming a sacrificial layer 131S on the upper surface 210a of the piezoelectric layer 210 so as to cover the upper electrode 311 at a position overlapping the excitation region. In Example Embodiment 3, the sacrificial layer 131S is a layer made of zinc oxide and is formed by sputtering, for example.

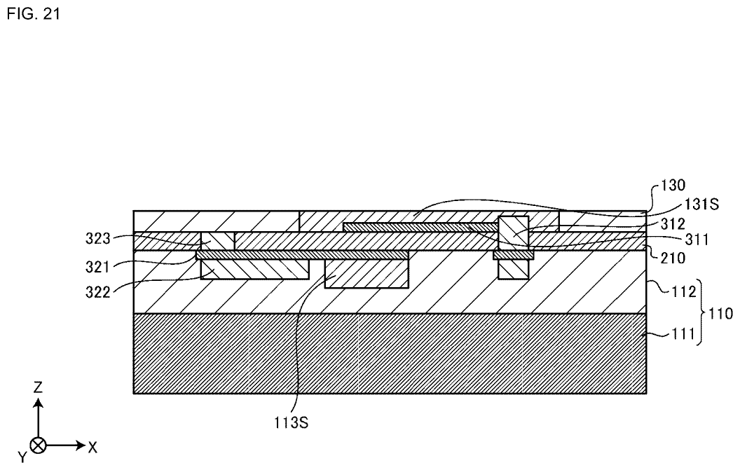

FIG. 21 is a diagram for describing a second intermediate layer forming step according to Example Embodiment 3. As illustrated in FIG. 21, in Example Embodiment 3, the intermediate layer forming step is a step of providing the intermediate layer 130 on the upper surface 210a of the piezoelectric layer 210 so as to cover the wiring electrode 323. In the intermediate layer forming step according to Example Embodiment 3, the intermediate layer 130 is formed and then ground such that the sacrificial layer 131S is exposed.

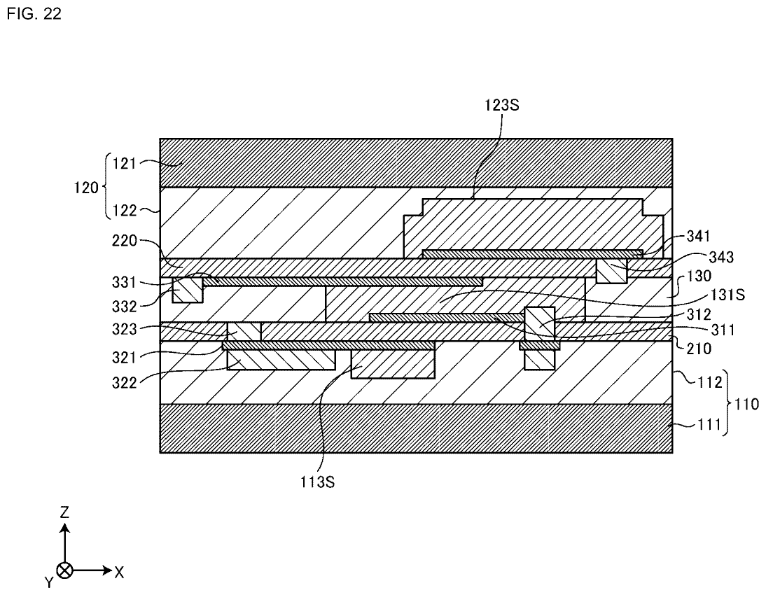

FIG. 22 is a schematic sectional view for describing a piezoelectric layer connecting step according to Example Embodiment 3. As illustrated in FIG. 22, in the piezoelectric layer connecting step according to Example Embodiment 3, the piezoelectric layer 210 of a multilayer body including the first resonator R1 and the piezoelectric layer 220 of a multilayer body including the second resonator R2 produced by a method the same as or similar to the method for producing the multilayer body including the first resonator R1 described above are connected via the intermediate layer 130 and the sacrificial layer 131S.

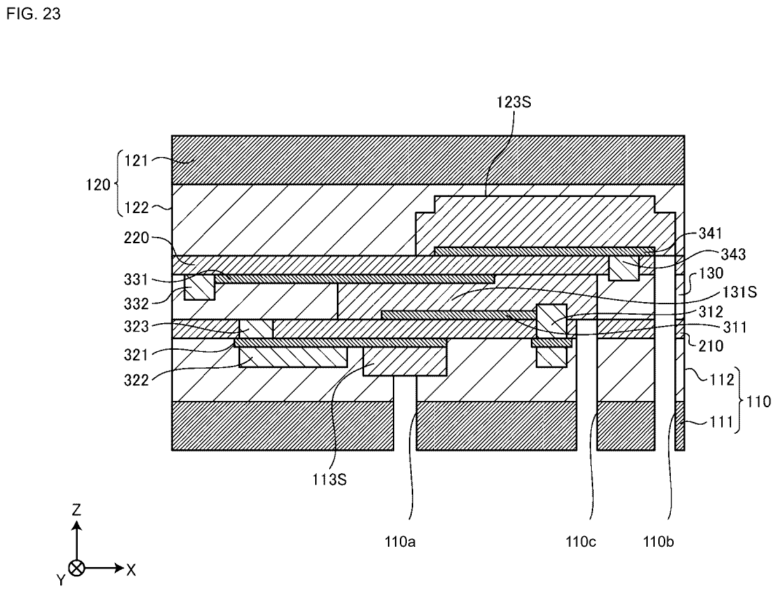

FIG. 23 is a diagram for describing a support through hole forming step according to Example Embodiment 3. As illustrated in FIG. 23, in the support through hole forming step, the through holes 110a, 110b, and 110c are formed so as to pass through from the opposite surface of the support 110 from the piezoelectric layer 210 to the sacrificial layers 113S, 123S, and 131S, respectively, in the Z direction. Also in Example Embodiment 3, the through holes 110a to 110c are formed by DRIE, for example.

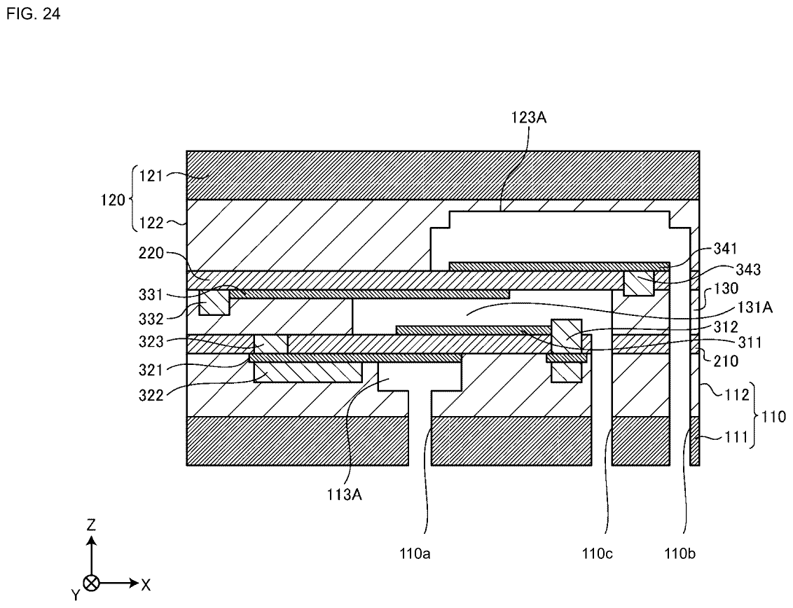

FIG. 24 is a diagram for describing a space portion forming step according to Example Embodiment 3. As illustrated in FIG. 24, the space portion forming step is a step of removing the sacrificial layers 113S, 123S, and 131S to form the space portions 113A, 123A, and 131A. In Example Embodiment 3, the sacrificial layers 113S, 123S, and 131S are removed by wet etching, for example. In this case, an etchant for dissolving the sacrificial layers 113S, 123S, and 131S is injected through the through holes 110a, 110b, and 110c, respectively.

Subsequently, a through electrode forming step the same as or similar to that in Example Embodiment 1 is performed. Thus, the piezoelectric device 1B according to Example Embodiment 3 is produced. The method for manufacturing the piezoelectric device 1B described above is merely an example. The method for manufacturing the piezoelectric device 1B is not limited thereto, and this method may be changed as appropriate.

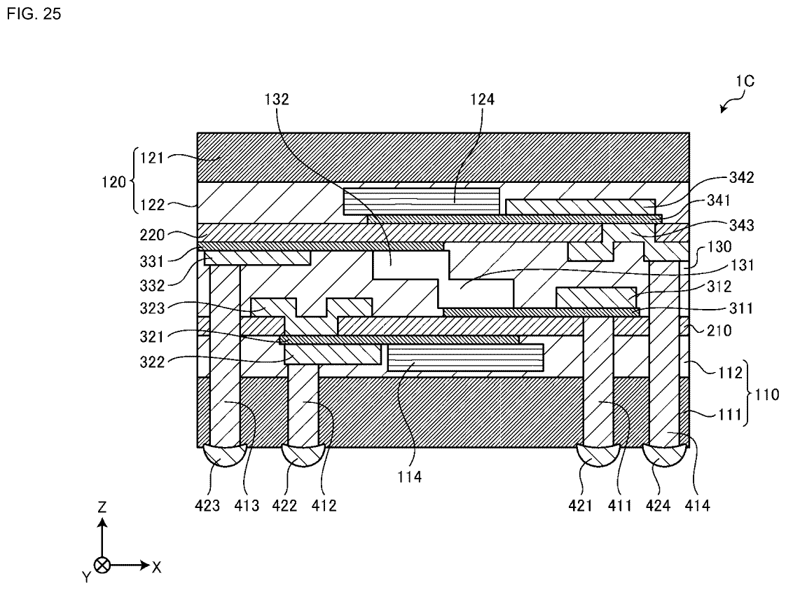

FIG. 25 is a schematic sectional view illustrating an example of a piezoelectric device according to Example Embodiment 4 of the present invention. As illustrated in FIG. 25, a piezoelectric device 1C according to Example Embodiment 4 differs from the piezoelectric device according to Example Embodiment 1 in that the support 110 and 120 includes acoustic multilayer films 114 and 124, instead of the space portions 113 and 123.

The acoustic multilayer films 114 and 124 are provided at respective positions overlapping at least portion of the first excitation region and at least portion of the second excitation region in plan view in the Z direction. The acoustic multilayer films 114 and 124 each have a structure in which low acoustic impedance layers whose acoustic impedance is relatively low and high acoustic impedance layers whose acoustic impedance is relatively high are alternately laminated on each other. The low acoustic impedance layer is made of, for example, SiO₂. The high acoustic impedance layer is, for example, a metal layer made of W or Pt or an intermediate layer made of tantalum oxide or silicon nitride. Thus, it is possible to confine bulk waves in the piezoelectric layers 210 and 220 without the space portions 113 and 123. The number of low acoustic impedance layers and high acoustic impedance layers laminated in each of the acoustic multilayer films 114 and 124 is not particularly limited. It is sufficient that at least one of the high acoustic impedance layers is located farther from the piezoelectric layer 210 than the low acoustic impedance layers and that at least one of the high acoustic impedance layers is located farther from the piezoelectric layer 220 than the low acoustic impedance layers.

The acoustic wave device according to Example Embodiment 4 is not limited to the example described above. For example, the intermediate layer 130 may include acoustic multilayer films instead of the space portions 131 and 132 of the intermediate layer 130.

As described above, in the piezoelectric device 1C according to Example Embodiment 4, when the region where the first upper electrode and the first lower electrode face each other in the first direction is the first excitation region and the region where the second upper electrode and the second lower electrode face each other in the first direction is the second excitation region, the first support includes a first acoustic multilayer film (acoustic multilayer film 114) located at a position overlapping at least portion of the first excitation region, and the second support includes a second acoustic multilayer film (acoustic multilayer film 124) located at a position overlapping at least portion of the second excitation region. The first acoustic multilayer film includes at least one low acoustic impedance layer having a lower acoustic impedance than the first piezoelectric layer, and at least one high acoustic impedance layer having a higher acoustic impedance than the first piezoelectric layer. The second acoustic multilayer film includes at least one low acoustic impedance layer having a lower acoustic impedance than the second piezoelectric layer, and at least one high acoustic impedance layer having a higher acoustic impedance than the second piezoelectric layer. Thus, bulk waves excited by the first resonator R1 and the second resonator R2 are reflected by the acoustic multilayer films 114 and 124. Accordingly, it is possible to improve the frequency characteristics.

The example embodiments described above are intended to facilitate understanding of the present invention and are not intended to construe the present invention in any limiting manner. The present invention may be modified and improved without departing from the scope of the present invention and includes equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric device comprising:
a first piezoelectric layer with a thickness in a first direction, and including an upper surface being one surface of the first piezoelectric layer in the first direction, and a lower surface being another surface of the first piezoelectric layer in the first direction;
a first support on a lower surface side of the first piezoelectric layer;
a first upper electrode on the upper surface of the first piezoelectric layer;
a first lower electrode on the lower surface of the first piezoelectric layer, and at least partially facing the first upper electrode;
a second piezoelectric layer including an upper surface being one surface of the second piezoelectric layer in the first direction, and a lower surface being another surface of the second piezoelectric layer in the first direction;
a second support on a lower surface side of the second piezoelectric layer;
a second upper electrode on the upper surface of the second piezoelectric layer;
a second lower electrode on the lower surface of the second piezoelectric layer, and at least partially facing the second upper electrode; and
an intermediate layer; wherein
the upper surface of the first piezoelectric layer and the upper surface of the second piezoelectric layer face each other in the first direction; and
the intermediate layer is located between the upper surface of the first piezoelectric layer and the upper surface of the second piezoelectric layer.

2. The piezoelectric device according to claim 1, further comprising:
a through electrode connected to at least one of the second upper electrode and the second lower electrode; wherein
the through electrode passes through the first support.

3. The piezoelectric device according to claim 1, wherein, when a region where the first upper electrode and the first lower electrode face each other in the first direction is a first excitation region and a region where the second upper electrode and the second lower electrode face each other in the first direction is a second excitation region, the first support includes a first space portion located at a position overlapping at least a portion of the first excitation region, and the second support includes a second space portion located at a position overlapping at least a portion of the second excitation region.

4. The piezoelectric device according to claim 3, wherein
the first support includes a through hole; and
the first space portion and the second space portion communicate with the through hole.

5. The piezoelectric device according to claim 1, wherein
when a region where the first upper electrode and the first lower electrode face each other in the first direction is a first excitation region and a region where the second upper electrode and the second lower electrode face each other in the first direction is a second excitation region, the first support includes a first acoustic multilayer film located at a position overlapping at least a portion of the first excitation region, and the second support includes a second acoustic multilayer film located at a position overlapping at least a portion of the second excitation region;
the first acoustic multilayer film includes at least one low acoustic impedance layer with a lower acoustic impedance than the first piezoelectric layer, and at least one high acoustic impedance layer with a higher acoustic impedance than the first piezoelectric layer; and
the second acoustic multilayer film includes at least one low acoustic impedance layer with a lower acoustic impedance than the second piezoelectric layer, and at least one high acoustic impedance layer with a higher acoustic impedance than the second piezoelectric layer.

6. The piezoelectric device according to claim 1, wherein, when a region where the first upper electrode and the first lower electrode face each other in the first direction is a first excitation region and a region where the second upper electrode and the second lower electrode face each other in the first direction is a second excitation region, the intermediate layer includes a space portion located at a position overlapping at least a portion of the first excitation region and at least a portion of the second excitation region in plan view in the first direction.

7. The piezoelectric device according to claim 6, wherein the space portion of the intermediate layer is sealed off from an outside of the piezoelectric device.

8. The piezoelectric device according to claim 6, wherein the first support includes a through hole communicating with the space portion in the intermediate layer.

9. The piezoelectric device according to claim 1, wherein each of the first piezoelectric layer and the second piezoelectric layer includes single-crystal lithium niobate, single-crystal lithium tantalate, or quartz crystal.

10. The piezoelectric device according to claim 1, wherein a thickness of each of the first and second piezoelectric layers is about 1 μm or less.

11. The piezoelectric device according to claim 1, wherein each of the first upper electrode and the first lower electrode includes a circular electrode.

12. The piezoelectric device according to claim 1, wherein each of the first upper electrode and the first lower electrode includes aluminum, platinum, copper, tungsten, or molybdenum, or an alloy including at least one of aluminum, platinum, copper, tungsten, or molybdenum.

13. The piezoelectric device according to claim 1, wherein each of the intermediate layers includes silicon oxide.

14. The piezoelectric device according to claim 1, wherein each of the second upper electrode and the second lower electrode includes a circular electrode.

15. The piezoelectric device according to claim 1, wherein each of the second upper electrode and the second lower electrode includes aluminum, platinum, copper, tungsten, or molybdenum, or an alloy including at least one of aluminum, platinum, copper, tungsten, or molybdenum.

16. The piezoelectric device according to claim 1, wherein a shortest distance between the upper surface of the first piezoelectric layer and the upper surface of the second piezoelectric layer is about 10 μm or less.

17. The piezoelectric device according to claim 2, wherein a plurality of the through electrodes pass through the first support.

18. The piezoelectric device according to claim 5, wherein the at least one low acoustic impedance layer of each of the first and second acoustic multilayer films includes SiO₂.

19. The piezoelectric device according to claim 5, wherein the at least one high acoustic impedance layer of each of the first and second acoustic multilayer films includes W or Pt.

20. The piezoelectric device according to claim 5, wherein the least one high acoustic impedance layer of each of the first and second acoustic multilayer films includes an intermediate layer including tantalum oxide or silicon nitride.
